(19) United States
(12) Patent Application Publication
(10) Pub. No.: US 2012/0083414 A1
(43) Pub. Date: Apr. 5, 2012

(54) METHOD OF MANUFACTURING A SUPERCONDUCTIVE ELECTRICAL CONDUCTOR, AND SUPERCONDUCTIVE CONDUCTOR

(76) Inventors: Rainer Soika, Hannover (DE); Beate West, Hannover (DE)

(21) Appl. No.: 13/220,809

(22) Filed: Aug. 30, 2011

(30) Foreign Application Priority Data
Oct. 5, 2010 (EP) 10 306 084.4

(51) Int. Cl. H01B 12/10; H01L 39/24

(52) U.S. Cl. 505/231; 505/431; 29/599; 174/125.1

(57) ABSTRACT

A method of manufacturing a superconductive electric conductor is indicated, which includes as the superconductive material as ceramic material. For carrying out the method, around a plurality of flat strips (1) of a carrier coated with a superconductive ceramic material, a longitudinally entering metal band (3) is formed into a pipe having a slot extending in the longitudinal direction, where the edges located at the slot next to each other are welded together. The strips (1) are fed to the pipe with continuous change of location in such a way that each strip along the length of the conductor assumes different positions over the cross section thereof. The pipe (9) closed by the welding procedure is subsequently reduced to an interior width which corresponds approximately to an enveloping curve of all strips (1) located in the pipe.

### RELATED APPLICATION

This application claims the benefit of priority from European Patent Application No. 10 306 084.4, filed on Oct. 5, 2010, the entirety of which is incorporated by reference.

### SPECIFICATION

The invention relates to a method of manufacturing a superconductive electrical conductor which has a ceramic material as superconductive material, and to a superconductive conductor (EP 1 916 720 B1).

A superconductive electrical conductor to be manufactured by the method according to the invention is composed of a composite material whose superconductive ceramic material changes over into the superconductive state at sufficiently low temperatures. The electrical direct current resistance of a conductor constructed from such a material is zero with sufficient cooling as long a certain current level is not exceeded. Suitable ceramic materials are, for example, BSCCO (bismuth-strontium-calcium-copper oxide) or ReBCO (rare earth-barium-copper oxide), particularly YBCO (yttrium-barium-copper oxide). Sufficiently low temperatures for bringing such a material into the superconductive state are, for example, between 67K and 110K. Suitable cooling agents are, for example, nitrogen, helium, neon and hydrogen or mixtures of these materials.

U.S. Pat. No. 5,739,086 describes various methods of manufacturing band-shaped electrical conductors which are referred to as high temperature superconductors. In a BSCCO superconductor, the BSCCO material is, for example, filled in the form of powder into a pipe of silver and is compacted. The superconductive state is reached by mechanical deformation of the pipe and subsequent thermal treatment (annealing). In the YBCO superconductor, initially at least one buffer layer is applied on a strip of metal as substrate, wherein the strip is, for example, biaxially textured, and wherein subsequently the YBCO material is applied on the buffer layer. The biaxially textured substrate is composed, for example, of nickel, copper or iron or an alloy of these materials. Used for the buffer layer are, for example, copper or silver. The YBCO material is subsequently brought into the superconductive state also by thermal treatment. The superconductive conductor manufactured in this manner can-as already mentioned-be used advantageously in electrical cables and coils for electric motors and magnets. However, because of its band shape it can only be bent in one direction.

Using the method according to the above mentioned EP 1 916 720 B1, a round superconductive conductor is manufactured which can be processed like a conventional wire without having to adhere to a specific direction during bending. Using this known method, a textured metal substrate which is present as a band is initially formed in its longitudinal direction around an elongated metal carrier having a circular cross section into a slotted pipe having edges extending in the longitudinal direction and resting against each other at a slot. The slotted pipe is subsequently closed by welding the slot. The closed pipe is then pulled down up to the stop at the carrier. The superconductive ceramic material is subsequently placed around the entire pipe and a final thermal treatment is carried out. This method has been found useful in practice, However, carrying out the method is relatively complicated.

The invention is based on the object of indicating a method which is simple to carry out for manufacturing a superconductive electrical conductor which has for direct current-as well as for alternating current transmission-a ⁻uniform current distribution in the entire cross section.

In accordance with the invention, this object is met in that, around a plurality of flat strips of a carrier coated with a superconductive ceramic material, a longitudinally entering metal band is formed into a pipe having a slot extending in the longitudinal direction, wherein the edges located at the slot next to each other are welded together, the strips are fed to the pipe with continuous change of placement in such a way that each strip assumes along the length of the conductor different positions in the cross section thereof, and the pipe closed by the welding procedure is subsequently reduced to an internal width which corresponds approximately to an enveloping curve of all strips located in the pipe.

In using this method, it is only necessary to sever a number of strips from a prefabricated band which has a carrier coated with superconductive material and are placed in the pipe. The pipe is formed, for example, in accordance with the state of the art known from EP 1 916 720 B1, of a longitudinally entering metal band and welded into a closed pipe.

Subsequently the closed pipe is reduced in its internal dimensions until it encloses the totality of the strips as closely as possible without applying pressure to the strips. The superconductive material is accommodated in the finished conductor within the pipe protected against mechanical damage. Therefore, the conductor produced according to this method can be used without taking any special precautionary measures and can be processed with conventional devices. Because of the continuous change of location of the strips while being supplied into the pipe, there is the additional advantage that the effect of current displacement (skin effect) known in the alternating current operation with respect to the current distribution in the conductor cross section is neutralized because, by using this method, the current flows through all strips. As a result, together with the plurality of strips located in the pipe with superconductive material, the conductor in the alternating current operation produces only small alternating current tosses in an appropriate cable.

Advantageously, in addition to the strips, a filler material is introduced into the pipe which together with the strips fills out the interior dimensions of the pipe. Such a material is preferably a metal which melts at low temperatures, which is filled in the liquid or viscous state into the pipe which is still open. It surrounds the strips in the finished conductor with the superconductive material in the solidified state, so that an electric connection of the conductor with other electric conductors is possible with conventional contact elements.

The method according to the invention and the conductor manufactured by the method are explained with the aid of the drawings of embodiments.

In the drawing:

FIG. 1 shows in a schematic illustration a device for carrying out the method according to the invention.

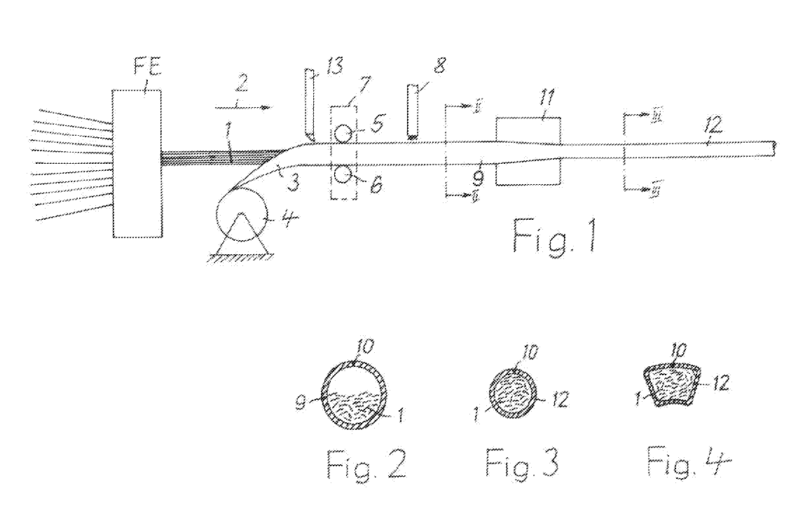

FIG. 2 is a sectional view, on a larger scale, along a section through FIG. 1 along the line II-II.

FIG. 3 shows the conductor according to the invention, also in an enlarged illustration, along line III-III through FIG. 1.

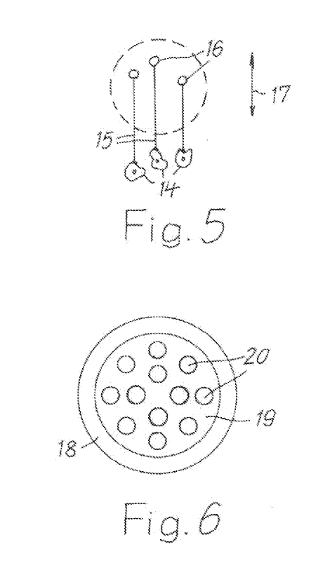

FIG. 4 shows the conductor in a cross sectional shape which is modified relative to FIGS. 2 and 3.

FIGS. 5 and 6 show a detail of the device according to FIG. 1 in two different embodiments.

For the conductor according to the invention the superconductive material used is generally ReBCO and particularly YBCO which is in the following description taken into consideration as specific ReBCO material.

The manufacture of bands with a carrier on which YBCO has been separated is disclosed, for example, in the above mentioned U.S. Pat. No. 5,739,086. Such bands are available on the market. They have widths of, for example, between 4 cm and 10 cm.

For carrying out the method according to the invention, a prefabricated band coated with YBCO is cut into strips which have a width, for example, of 0.2 mm to 0.4 mm. The word “strip” used in the following is such a narrow flat strip of a carrier coated with YBCO. These strips can initially be severed from a band and wound onto a coil. However, they can also be processed further directly following the severing process.

For manufacturing the superconductive conductor, advantageously a metal band traveling in the longitudinal direction can be shaped and welded around a plurality of flat strips with superconductive material, without carrying out the permanent placement change already at this time. In this manner, a round wire containing a plurality of strips is produced. The permanent change of place of the strips in the cross section of the conductor is achieved by stranding together several of such prefabricated round wires with a predeterminable pitch length, and this without backward rotation. In this connection, additionally a central core element can be provided around which the round wires are stranded. Because the round wires did not perform a backward rotation as stranding elements, a change in place of the strips is achieved in the cross section of the resulting arrangement, i.e., the conductor. This has the result that all strips have over the length of the conductor the same average spacing from the center. Consequently, a uniform distribution of the alternating current in the strips or in the conductor is achieved.

The method according to the invention can be carried out according to FIGS. 5 and 6 which schematically show possible devices for feeding the strips with superconductive material.

A larger number of strips 1 is moved in the direction of the arrow 2 by means of a withdrawal device which is not also illustrated. This causes the strips 1 to travel through a guiding device FE whose possible manner of operation is explained further below in connection with FIGS. 5 and 6. in the guiding device FE the strips 1 are continuously subjected to a place change. After leaving the guiding device FE, a metal band 3, which can be pulled from a coil 4 by means of the same withdrawal device as the strips 1, can be shaped in a shaping device 7 indicated by two rollers 5 and 6 by entering longitudinally to form a pipe with a slot extending in the longitudinal direction where the edges of the metal band 3 rest against each other. The slot is subsequently welded in a welding device 8. The pipe 9 which is now closed is illustrated in FIG. 2. The strips 1 are located in the lower portion of the pipe 9 which is closed by a welding seam 10 in the upper area.

The metal band 3 may be composed, for example, of copper, aluminum or high grade steel, but also of an alloy of these materials such as, for example, of bronze.

In a drawing unit 11 following in the withdrawing direction (arrow 2), the pipe 9 is reduced to an interior width which corresponds approximately to an enveloping curve of all strips 1 placed in the pipe 9, so that it almost contacts the strips 1 without exerting any pressure on the strips 1. The superconductive conductor 12 manufactured in this manner is illustrated, for example, in FIG. 3.

Additional filling material can be placed in the pipe which is still open by means of a feeding device 13. Used as filler material is preferably a low-melting metal which is filled into the pipe in the liquid or viscous state and which is solid at room temperature and especially at the low temperatures required for producing the superconductivity. Such a metal is, for example, Wood's metal which melts at approximately 73 to 77° C., or Rose's metal having a melting point at about 95° C.

The conductor 9 or 12 is circular as illustrated in FIGS. 2 or 3. However, it can also have a cross section which deviates from the circular shape, for example, with a polygonal cross sectional shape. The respective cross sectional shape can advantageously be produced in the drawing unit 11. In the embodiment illustrated in FIG. 4, the conductor 12 has an approximately trapezoidal cross section with two curved side surfaces located opposite each other. Such a conductor is particularly suitable as an individual element for building up a conductor strand from a plurality of such conductors.

The guiding unit FE can be constructed differently. if possible, the unit should operate with conventional elements which are known from cable technology. Two possible embodiments of the guide unit FE are illustrated in FIGS. 5 and 6.

The guide unit FE according to FIG. 5 has a plurality of only schematically indicated cam disks 14 which are rotated about their axes when the method is carried out. Resting against the circumferential surfaces of the cam disks 14 are the ends of rods 15 which at their other ends are each equipped with eyes 16 through which always at least one strip 1 extends when the method is being carried out. By rotating the cam disks 14, the eyes 16 are moved back and forth in the direction of double arrow 17. Consequently, they continuously occupy a different place in the cross section of the pipe 9 which is illustrated in FIG. 5 by a circle 18 indicated by broken lines.

The cam disks 14 can be rotated continuously with uniform speed about their axes so that a targeted systematic distribution of the strips 1 in the cross section of the conductor is obtained. However, the cam disks 14 can also be driven with changing speed. This results in a more random distribution of the strips 1 in the cross section of the conductor.

The strips 1 can in another embodiment of the method be combined into several bundles in a prefabrication step, wherein the bundles are each wound onto a coil. The coils can be arranged in stranding frames of stranding machines which are conventional in cable technology, or in stationary run-off frames.

The guide unit FE is composed in this embodiment according to FIG. 6, for example, of a disk 19 supported in a frame 18, wherein the disk 19 is rotatable about its axis. The disk 19 has several throughholes 20 for passing through the prefabricated. bundles of strips. The disk can be rotated about its axis in a constant direction together with the stranding frame supporting the bundles. However, it can also be rotated with a reversing direction of rotation. This provides the advantage that fixed process sequences can be used for the coils of the bundles.

1. Method of manufacturing a superconductive electrical conductor which has as the superconductive material a ceramic material, said method comprising:
around a plurality of flat strips of a carrier coated with a superconductive ceramic material, a longitudinally entering metal band is formed into a pipe having a slot extending in the longitudinal direction, wherein the edges located at the slot next to each other are welded together;
the strips are fed to the pipe with continuous change of location in such a way that each strip occupies along the length of the conductor different positions over the cross section thereof; and
the pipe dosed by the welding procedure is subsequently reduced to an interior width which corresponds approximately to an enveloping curve of all strips contained in the pipe.

2. Method according to claim 1, wherein the change of location of e strips is carried out systematically in a targeted manner.

3. Method according to claim 1, wherein the change of location of the strips is carried out with random distribution.

4. Method according to claim 1, wherein the strips are initially brought together in several bundles which are separate from each other, wherein the bundles are during their feeding to the pipe moved in the circumferential direction in relation to the pipe cross section.

5. Method according to claim 1, wherein, initially, several round wires are manufactured in which several strips are combined in a common sheathing, and the round wires are stranded together without return rotation.

6. Method according to claim 5, wherein the round wires are stranded together around a central core element.

7. Method according to claim 1, wherein filling material is filled into the pipe next to the strips.

8. Method according to claim 7, wherein a low-melting metal is used as filling material.

9. Superconductive, electrical conductor manufactured by the method according to claim 1, wherein
a plurality of flat strips of a carrier coated with superconductive ceramic material is arranged in a pipe composed of metal whose internal cross section is almost completely filled out by the strips; and
the strips assume along the length of the conductor different positions over the cross section thereof.

10. Conductor according to claim 9, wherein said conductor has a circular cross section.

11. Conductor according to claim 9, wherein said conductor has a trapezoidally shaped cross section with two curved side surfaces located opposite each other.
